(19) United States
(12) Patent Application Publication
(10) Pub. No.: US 2026/0038781 A1
(43) Pub. Date: Feb. 5, 2026

(54) SEMICONDUCTOR PROCESS EQUIPMENT FOR LIGHT ABSORPTION-BASED RADICAL CONCENTRATION MEASUREMENT AND METHOD USING THE SAME

(71) Applicant: Samsung Electronics Co., Ltd., Suwon-si (KR)

(72) Inventors: Soonku KWON, Suwon-si (KR); Sunggil KANG, Suwon-si (KR); Woojin NAM, Suwon-si (KR); Sungyong PARK, Suwon-si (KR); Junyoung BAE, Suwon-si (KR); Hangyul LEE, Suwon-si (KR); Inhye JEONG, Suwon-si (KR); Chanyeong JEONG, Suwon-si (KR)

(73) Assignee: Samsung Electronics Co., Ltd., Suwon-si (KR)

(21) Appl. No.: 19/269,626

(22) Filed: Jul. 15, 2025

(30) Foreign Application Priority Data
Aug. 1, 2024 (KR) 10-2024-0102417

(51) Int. Cl. H01J 37/32; G01N 21/31

(52) U.S. Cl. CPC H01J 37/32972; G01N 21/31; H01J 2237/3341

(57) ABSTRACT

A semiconductor process equipment may include a chamber including a viewport, a light source configured to generate light, a light path controller configured to direct the light into the chamber through the viewport at a target height and a target incidence angle, and receive reflected light through the viewport when the light is reflected by an interior surface of the chamber, and a detector configured to detect spectral characteristics of the reflected light, and measure a radical concentration in the chamber along an optical path of the light and the reflected light based on the detected spectral characteristics.

### CROSS-REFERENCE TO RELATED APPLICATION

This U.S. non-provisional application is based on and claims the benefit of priority under 35 U.S.C. § 119 to Korean Patent Application No. 10-2024-0102417, filed on Aug. 1, 2024, in the Korean Intellectual Property Office, the disclosure of which is incorporated by reference herein in its entirety.

### BACKGROUND

One or more example embodiments of the inventive concepts relate to semiconductor processing equipment for radical concentration measurement based on light absorption, systems including the semiconductor processing equipment, and/or methods for using the semiconductor process equipment, etc.

A semiconductor cleaning process may include wet cleaning and/or dry cleaning. In wet cleaning, chemical solutions may be used. Wet cleaning may have limitations and/or restrictions when used in fine processes due to the surface tension of chemical solutions used during wet cleaning. Highly reactive gases and/or radicals may be used in dry cleaning. Plasma may be generated in dry cleaning, and radicals produced in this process may be selectively provided to a wafer. Contaminants on the wafer may be removed based on the high reactivity of the gases and/or radicals.

### SUMMARY

According to an aspect of at least one example embodiment of the inventive concepts, there is provided semiconductor process equipment including a chamber including a viewport, a light source configured to generate light, a light path controller configured to, direct the light into the chamber through the viewport at a target height and a target incidence angle, and receive reflected light through the viewport when the light is reflected by an interior surface of the chamber, and a detector configured to, detect spectral characteristics of the reflected light, and measure a radical concentration in the chamber along an optical path of the light and the reflected light based on the detected spectral characteristics.

According to at least one example embodiment of the inventive concepts, there is provided semiconductor process equipment including a chamber, a light source configured to generate light, a light emitter configured to direct the light into the chamber at a target height and a target incidence angle by using a mirror, a light receiver configured to receive reflected light using the mirror when the light is reflected by an inside wall of the chamber, and a detector configured to detect spectral characteristics of the reflected light to measure a radical concentration in the chamber along an optical path of the light and the reflected light.

According to at least one example embodiment of the inventive concepts, there is provided semiconductor process equipment including a chamber, a light source configured to generate light, a light path controller configured to direct the light into the chamber by sequentially using a target height and a target incidence angle that are sequentially selected from reference heights and reference incidence angles and receive reflected light through the viewport of the chamber when the light is reflected by an inside wall of the chamber; and a detector configured to detect spectral characteristics of the reflected light to measure a radical concentration in the chamber along an optical path of the light and the reflected light.

### BRIEF DESCRIPTION OF THE DRAWINGS

Some example embodiments will be more clearly understood from the following detailed description taken in conjunction with the accompanying drawings in which:

FIG. 1 is a diagram illustrating a configuration of semiconductor processing equipment for measuring radical concentration based on light absorption, according to at least one example embodiment;

FIG. 2 is a diagram illustrating zones used to measure radical concentration distribution according to at least one example embodiment;

FIG. 3 is a diagram illustrating a configuration of a light path controller according to at least one example embodiment;

FIG. 4 is a diagram illustrating an incidence angle adjustment operation of a light path controller according to at least one example embodiment;

FIG. 5 is a diagram illustrating an incidence height adjustment operation of a light path controller according to at least one example embodiment;

FIGS. 6 and 7 are diagrams illustrating an example in which optical paths are formed in a center zone according to at least one example embodiment;

FIGS. 8 and 9 are diagrams illustrating an example in which optical paths are formed in a middle zone according to at least one example embodiment;

FIGS. 10 and 11 are diagrams illustrating an example in which optical paths are formed in an edge zone according to at least one example embodiment;

FIG. 12 is a diagram illustrating an incidence angle according to at least one example embodiment;

FIG. 13 is a diagram illustrating a distribution control operation based on results of radical concentration distribution measurement according to at least one example embodiment;

FIG. 14 is a diagram illustrating a configuration of semiconductor processing equipment for controlling radical distribution according to at least one example embodiment; and

FIG. 15 is a flowchart illustrating a method of measuring the concentration of radicals based on light absorption, according to at least one example embodiment.

### DETAILED DESCRIPTION

Hereinafter, some example embodiments are described with reference to the accompanying drawings. In the drawings, like reference numerals denote like elements, and repeated descriptions thereof are omitted.

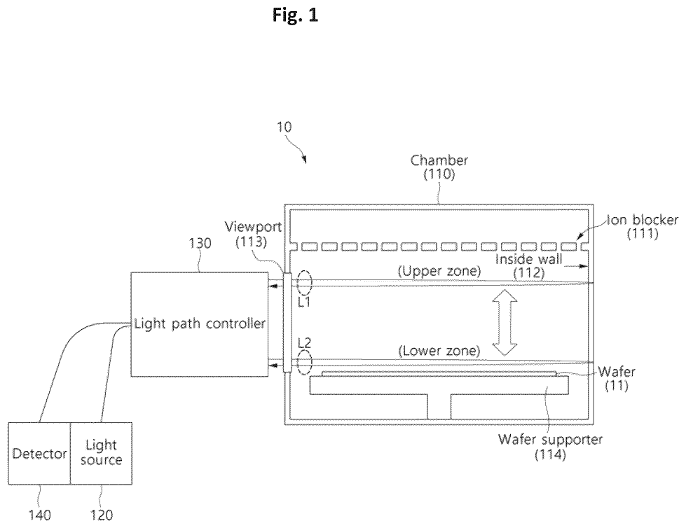

FIG. 1 is a diagram illustrating a configuration of semiconductor processing equipment 10 for measuring radical concentration based on light absorption, according to at least one example embodiment. Referring to FIG. 1, the semiconductor processing equipment 10 may include at least one chamber 110, at least one light source 120, at least one light path controller 130, and/or at least one detector 140, etc., but is not limited thereto, and for example, may include a greater or lesser number of constituent components. The semiconductor processing equipment 10 and the chamber 110 may be used for dry cleaning processes, but are not limited thereto.

Wet cleaning may show limitations (e.g., restrictions, etc.) when used in fine processes (for example, at the level of several nanometers (nm)) due to the surface tension of liquid. In other words, wet cleaning may not be used and/or may be detrimental for fine processes due to the surface tension of the chemicals used during wet cleaning. The limitations of wet cleaning may be overcome by dry cleaning using highly reactive gases and/or radicals. In a dry cleaning process, gas and/or radicals may be supplied into the chamber 110, and the gas and/or radicals may selectively etch a specific material of a wafer 11 through a chemical reaction.

The chamber 110 may have a cylindrical structure. The chamber 110 may include at least one metal. For example, the material of the chamber 110 may be aluminum (Al), but is not limited thereto. The chamber 110 may be electrically grounded. An opening may be formed in a side wall of the chamber 110 and may be used as an entrance for loading and/or unloading the wafer 11. An exhaust pipe may be connected to a bottom wall of the chamber 110 to discharge byproducts generated during processes. The exhaust pipe may be equipped with at least one pump to maintain a process pressure inside the chamber 110 during processes and a valve to open and/or close at least one path in the exhaust pipe.

The chamber 110 may include an ion blocker 111 and/or a wafer supporter 114, etc., but is not limited thereto. The wafer supporter 114 may be an electrostatic chuck configured to fix the wafer 11 by electrostatic force, but is not limited thereto. The wafer supporter 114 may generally have a disk shape, but is not limited thereto, and for example, may have a polygonal shape, etc. The wafer supporter 114 may fix the wafer 11 by a method such as an electrostatic method and/or a mechanical clamping method, etc.

At least one heating element (e.g., a heating device, a heater, etc.) may be installed inside the wafer supporter 114 as a unit for heating the wafer 11. Heat generated by the heating element may be transferred to the wafer 11, and owing to the heat, the wafer 11 may be maintained at a temperature desired and/or required for processing. At least one cooling path forming a wafer cooling unit (e.g., a wafer cooler, a cooler, etc.) may be inside the wafer supporter 114, and at least one coolant may be supplied to the cooling path. While flowing along the cooling path, the coolant may cool the wafer 11, and thus, the wafer 11 may be maintained at a temperature desired and/or required for processing.

The ion blocker 111 may include at least one conductive material and may be shaped like a plate, such as a disk, etc., but is not limited thereto. A constant voltage (for example, ground voltage, etc.) may be connected to the ion blocker 111, but the example embodiments are not limited thereto. An upper space above the ion blocker 111 may be a space for generating plasma, and a lower space under the ion blocker 111 may be a process space for processing the wafer 11, but the example embodiments are not limited thereto. Process gas may be supplied to the upper space, and when an electromagnetic field is generated in the upper space above the ion blocker 111, the process gas may be excited into a plasma state. The process gas excited into a plasma state may include radicals, ions, and/or electrons. Radicals may pass through the ion blocker 111 and reach the wafer 11 placed in the lower space under the ion blocker 111. Neutral gas may also pass through the ion blocker 111 and reach the wafer 11.

Uniform distribution of gas and/or radicals may be desired and/or required inside the chamber 110 to improve and/or ensure balanced cleaning of the wafer 11. Due to the trend of using larger wafers to produce more integrated circuit chips during a single process, the desire and/or need to measure and/or control the distribution of gas and/or radicals may increase to uniformly process the entire areas of wafers.

In the related art, an analysis method using a residual gas analyzer (RGA) installed on a fore-line stage is used to monitor byproducts generated by the reaction of an etchant and/or substances used in dry cleaning. However, it may be difficult to determine the condition of an etchant and/or byproducts present on the surface of the wafer 11 by using the analysis method.

In addition, optical absorption spectroscopy (OAS) is used in the related art to analyze the amount of absorbed light after light passes through two opposing viewports. However, it may be difficult to implement two opposing viewports in dense structures such as a twin-chamber structure designed to reduce the area of semiconductor equipment. Moreover, in reflective-OAS (R-OAS), light reflected by an inside wall 112 of the chamber 110 is used via one viewport 113 without additional structures inside the chamber 110. However, OAS or R-OAS measures the distribution of radicals by using light passing through a center zone of the chamber 110, and thus, it may be difficult to measure the distribution of radicals in other zones of the chamber 110 by using OAS or R-OAS.

According to at least one example embodiment, the concentration of radicals may be measured in various zones defined within a three-dimensional (3D) space of the chamber 110, and the distribution of radical concentration inside the chamber 110 may be derived based on results of the measurement. According to at least one example embodiment, the concentration of radicals may be measured separately in a plurality of zones (e.g., the upper and lower zones) of the chamber 110 to predict the lifetime of radicals. Additionally, even when a process gap changes, the concentration of radicals may be measured by adjusting a light incidence height according to and/or based on the changed process gap. In addition, when the wafer supporter 114 has a moving function (e.g., the wafer supporter 114 may move, etc.), the concentration of radicals may be measured by adjusting the light incidence height based on the position of the wafer supporter 114.

The light source 120 may generate and/or emit light. The light source 120 may include a laser, a light-emitting diode (LED), a halogen lamp, a xenon lamp, or any combinations thereof, but is not limited thereto. The light source 120 may provide light to the light path controller 130 via an optical fiber, but is not limited thereto.

The light path controller 130 may direct light into the chamber 110 at a target height and a target incidence angle through the viewport 113 and may receive light reflected by the inside wall 112 (e.g., interior surface) of the chamber 110 through the viewport 113. The inside wall 112 may have a cylindrical structure and include a light-reflective material, but is not limited thereto, and for example, may be structured to have other shapes. The chamber 110 may not include additional reflectors other than the inside wall 112 for reflecting light inside the chamber 110, but is not limited thereto. The viewport 113 may be a single viewport of the chamber 110. Light may be reflected at least once by the inside wall 112, and light reflected at least once by the inside wall 112 may be referred to as reflected light.

The incidence height of light may refer to the shortest distance between the incidence position of the light and the bottom surface of the chamber 110. The incidence height of light may be measured in a direction perpendicular to the bottom surface of the chamber 110. The incidence angle of light may refer to an angle between an optical path of the light and a line that connects the center of the bottom surface of the chamber 110 to the incidence position of the light when the optical path of the light is projected onto the bottom surface of the chamber 110.

Reference heights and reference incidence angles may be defined based on one or more zones inside the chamber 110. For example, the zones may include an upper center zone, an upper middle zone, an upper edge zone, a lower center zone, a lower middle zone, and/or a lower edge zone, but are not limited thereto.

Reference heights and reference incidence angles may be set such that an optical path of light may pass through all of the zones inside the chamber 110. For example, a first reference height for forming an optical path passing through an upper zone may be defined, and a second reference height for forming an optical path passing through a lower zone may be defined, but the example embodiments are not limited thereto, and for example there may be a single reference height or more than two reference heights. For example, a first incidence angle for forming an optical path passing through a center zone, a second incidence angle for forming an optical path passing through a middle zone, and a third incidence angle for forming an optical path passing through an edge zone may be defined, etc. FIG. 1 may show an example in which an optical path of a first light beam L1 passing through an upper zone and an optical path of a second light beam L2 passing through a lower zone are sequentially adjusted by the light path controller 130. FIG. 1 illustrates an example in which a target height is adjusted. However, a target height and a target incidence angle may be adjusted together as described below.

The light path controller 130 may control an optical path of light by sequentially using a target height and a target incidence angle that are sequentially selected from one or more reference heights and/or one or more reference incidence angles. The concentration of radicals in the zones of the chamber 110 may be sequentially measured by sequentially using the target height and the target incidence angle. For example, the first reference height and the first incidence angle may be respectively set as the target height and the target incidence angle, and in this case, an optical path passing through the upper center zone may be formed. Then, the first reference height and the second incidence angle may be respectively set as the target height and the target incidence angle, and in this case, an optical path passing through the upper middle zone may be formed. Then, the first reference height and the third incidence angle may be respectively set as the target height and the target incidence angle, and in this case, an optical path passing through the upper edge zone may be formed. Then, optical paths passing through lower zones may be sequentially formed based on the second reference height, the first incidence angle, the second incidence angle, and the third incidence angle, etc. However, the example embodiments are not limited thereto, and any number of reference heights and/or incidence angles may be used to measure the concentration of radicals in the one or more zones of the chamber 110.

The detector 140 may detect spectral characteristics of reflected light to measure the concentration of radicals in the chamber 110 along an optical path of light and the reflected light. The light path controller 130 may provide the reflected light to the detector 140 via an optical fiber, but the example embodiments are not limited thereto. The spectral characteristics of the reflected light may indicate the intensity of the reflected light in each wavelength band. Radicals may absorb specific wavelengths of light along an optical path of the light. The concentration of radicals along an optical path of light may be measured by analyzing light absorption along the optical path based on spectral characteristics of reflected light. The concentration of radicals may be determined based on the Beer-Lambert law. For example, Equation 1 below may be used to calculate the concentration of radicals.

$$\frac{{I}_{abs .}}{{I}_{0}} ( λ ) = exp [ - nl σ ( λ ) ] \qquad [ Equation 1 ]$$

In Equation 1, I₀ may refer to the intensity of incident light, I_{abs} may refer to the intensity of reflected light, n may refer to the concentration of radicals, l may refer to the length of an optical path of interest, λ may refer to wavelength, and σ(λ) may refer to a cross-sectional area of absorption. The spectrum of reflected light may be an absorption spectrum. The optical path of interest may refer to an optical path of a zone to be measured within the entire optical path. For example, when measuring the concentration of radicals in a center zone, light may be directed into the chamber 110 at a target incidence angle toward the center zone. In this case, however, the light may pass through not only the center zone, but also the middle and edge zones. The length of an optical path may be adjusted and/or corrected to improve accuracy. For example, because the center zone is a zone of interest (e.g., a target zone, etc.), a length corresponding to the length of the center zone rather than the total length of the optical path may be determined as the length of the optical path of interest.

According to some example embodiments, the detector 140 may include processing circuitry to perform the measurement of the concentration of radicals based on the detect spectral characteristics of the reflected light in the chamber 110 along an optical path of light and the reflected light using Equation 1. The processing circuitry may include hardware or hardware circuit including logic circuits; a hardware/software combination such as a processor executing software and/or firmware; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc., but is not limited thereto.

Radicals and/or neutral gas may be used for dry cleaning. In some example embodiments, descriptions of radicals may also be applied to neutral gas. In other words, the distribution of radical concentration and/or the distribution of neutral gas concentration may be measured according to some example embodiments.

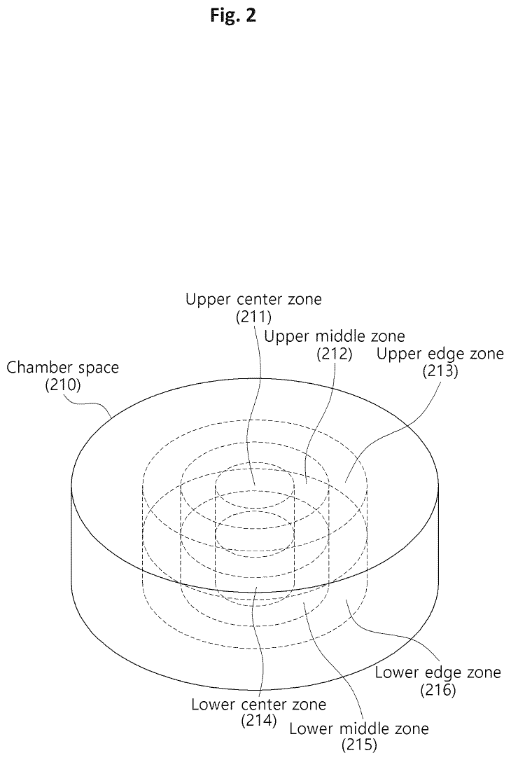

FIG. 2 is a diagram illustrating a plurality of zones used to measure the distribution of radical concentration according to at least one example embodiment. Referring to FIG. 2, a chamber space 210 may include at least one zone, such as an upper center zone 211, an upper middle zone 212, an upper edge zone 213, a lower center zone 214, a lower middle zone 215, and/or a lower edge zone 216, etc. As illustrated in FIG. 2, the plurality of zones may be circular shaped and may concentrically radiate from a center zone, etc. However, FIG. 2 illustrates an example, and the chamber space 210 may be divided into zones different from those illustrated in FIG. 2, and for example, the chamber zone 210 may include a greater or lesser number of zones, may have differently positioned zones, may have differently shaped zones, etc. The chamber space 210 may refer to a space of a chamber in which the concentration of radicals is to be measured and/or measured. For example, the chamber space 210 may refer to a space between an ion blocker and a wafer supporter, but is not limited thereto. When the position of the wafer supporter changes, upper and lower zones may be set according to and/or based on the change. According to some example embodiments, optical path control may be performed to measure the concentration of radicals in each zone of the chamber space 210 such as the upper center zone 211, the upper middle zone 212, the upper edge zone 213, the lower center zone 214, the lower middle zone 215, and the lower edge zone 216, and the distribution of the concentration of radicals may be monitored, but the example embodiments are not limited thereto, and for example, measurement of one or more zones may be omitted, etc.

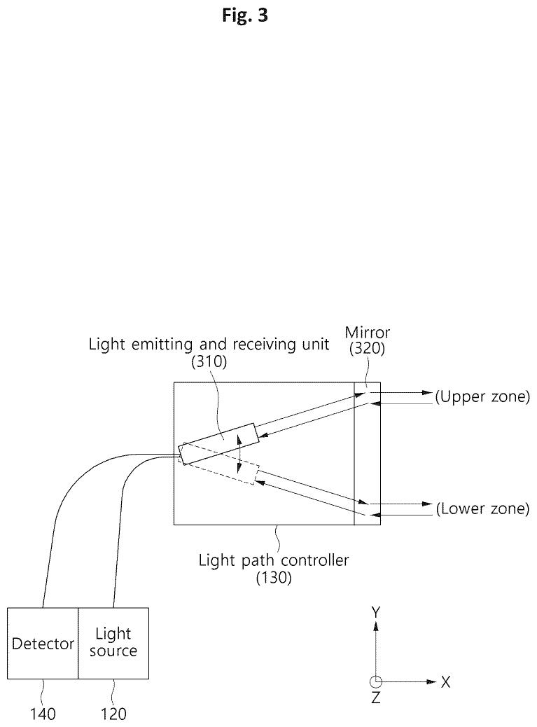

FIG. 3 is a diagram illustrating a configuration of a light path controller 130 according to at least one example embodiment. Referring to FIG. 3, the light path controller 130 may include a light emitting and receiving unit 310 and/or at least one mirror 320, etc. The light emitting and receiving unit 310 (e.g., light emitting and receiving device, etc.) may include a light emitter configured to direct light into a chamber and a light receiver configured to receive light reflected from an inside wall (e.g., inside surface, interior surface, etc.) of the chamber. The light emitter may direct light into the chamber using the mirror 320, and the light receiver may receive reflected light using the mirror 320. According to at least one example embodiment, the light emitter and the light receiver may each include a collimator and/or a coupler to improve light focusing and collimation, but the example embodiments are not limited thereto. The mirror 320 may reflect light emitted by the light emitter toward the inside of the chamber, and when the light is reflected by the inside wall of the chamber, the mirror 320 may reflect the reflected light toward the light receiver.

At least one of the light emitting and receiving unit 310 and the mirror 320 may have an angle adjustment function. When the light emitting and receiving unit 310 has an angle adjustment function, at least one of the light emitter and the light receiver of the light emitting and receiving unit 310 may have an angle adjustment function. For example, the light path controller 130 may include an actuator that implements the angle adjustment function of at least one of the light emitting and receiving unit 310 and the mirror 320, etc. The actuator may adjust the angle of at least one of the light emitting and receiving unit 310 and the mirror 320, etc.

According to some example embodiments, the angle of the light emitting and receiving unit 310 may be adjusted by an actuator connected to the light emitting and receiving unit 310, and the angle of the mirror 320 may be adjusted by an actuator connected to the mirror 320, etc., but the example embodiments are not limited thereto. For example, the incidence height of light may be adjusted by adjusting the angle of the light emitting and receiving unit 310, and the incidence angle of the light may be adjusted by adjusting the angle of the mirror 320. In this case, the angle of the light emitting and receiving unit 310 may correspond to an altitude angle, and the angle of the mirror 320 may correspond to an azimuth angle, but the example embodiments are not limited thereto. In another example, the incidence angle of light may be adjusted by adjusting the angle of the light emitting and receiving unit 310, and the incidence height of the light may be adjusted by adjusting the angle of the mirror 320, etc. In this case, the angle of the light emitting and receiving unit 310 may correspond to an azimuth angle, and the angle of the mirror 320 may correspond to an altitude angle, etc.

FIG. 3 shows an example in which the incidence height of light is adjusted by adjusting the angle of the light emitting and receiving unit 310. As the incidence height of light is adjusted, the concentration of radicals in an upper zone and the concentration of radicals in a lower zone may be sequentially measured. In an example described below, the incidence height of light may be adjusted by adjusting the angle of the light emitting and receiving unit 310, and the incidence angle of the light may be adjusted by adjusting the angle of the mirror 320. However, contrary to the example, in some example embodiments, the incidence angle of light may be adjusted by adjusting the angle of the light emitting and receiving unit 310 and/or the incidence height of the light may be adjusted by adjusting the angle of the mirror 320, etc.

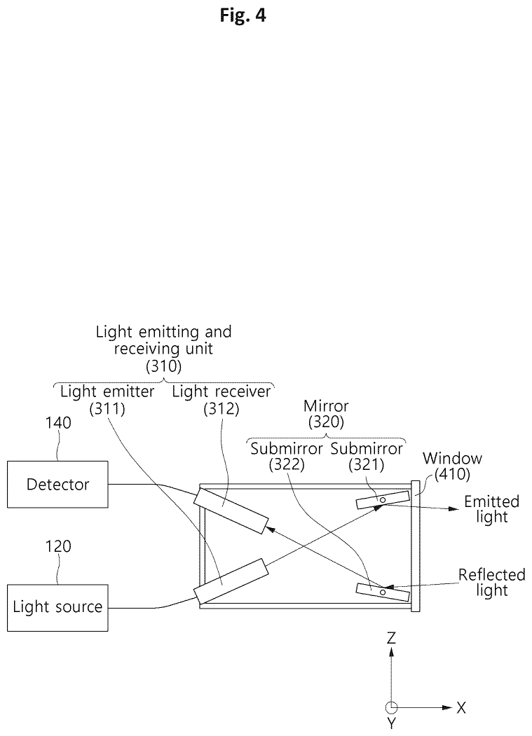

FIG. 4 is a diagram illustrating an operation of adjusting the incidence angle of a light path controller according to at least one example embodiment. Referring to FIG. 4, a light emitting and receiving unit 310 may include a light emitter 311 configured to direct light into a chamber, and may include a light receiver 312 configured to receive light reflected from an inside wall of the chamber, etc., but is not limited thereto. The light emitter 311 and the light receiver 312 may face at least one mirror 320. The light emitter 311 may direct light into the chamber using the mirror 320, and the light receiver 312 may receive reflected light using the mirror 320, etc. The light emitter 311 and the light receiver 312 may form a symmetrical structure, but is not limited thereto.

The mirror 320 may be, for example, a concave mirror with a curvature for directing light in a direction parallel to a wafer supporter of the chamber, but is not limited thereto, and for example, the mirror 320 may include a plurality of submirrors arranged to direct the light in a desired direction with respect to the wafer supporter, etc. According to at least one example embodiment, the mirror 320 may include submirrors 321 and 322, etc., but is not limited thereto. The submirrors 321 and 322 may form a symmetrical structure, but are not limited thereto. The submirror 321 may reflect light output from the light emitter 311 toward the inside of the chamber. When light is reflected from the inside wall of the chamber, the submirror 322 may reflect the reflected light toward the light receiver 312. Both the submirrors 321 and 322 may be concave mirrors with a curvature for directing light in a direction parallel to the wafer supporter of the chamber, but are not limited thereto, and for example, and the submirrors 321 and/or 322 may each include a plurality of submirrors arranged to direct the light in a desired direction with respect to the wafer supporter. The submirror 321 may direct light provided by the light emitter 311 into the chamber in a desired direction with respect to the wafer supporter, such as a direction parallel to the wafer supporter, regardless of the angle of the light emitter 311. When reflected light is output from the chamber and incident on the submirror 322, the submirror 322 may provide the reflected light to the light receiver 312 regardless of the angle of the light receiver 312.

Incident light and/or reflected light may pass through at least one window 410. The window 410 may have a transmittance that allows incident light and reflected light to pass through the window 410. The rest of the light path controller, except for the window 410, may be constructed as a case to block external light.

At least one of the light emitter 311, the light receiver 312, and the mirror 320 may have an angle adjustment function. FIG. 4 may illustrate an example in which each of the light emitter 311, the light receiver 312, and the mirror 320 has an angle adjustment function. However, the example embodiments are not limited thereto. In the example illustrated in FIG. 4, actuators may be provided respectively for the light emitter 311, the light receiver 312, and/or the mirror 320, thereby providing the angle adjustment function. Actuators may be provided respectively for the submirrors 321 and 322.

The angle of the light emitter 311 and/or the angle of the light receiver 312 may be adjusted by actuators respectively connected to the light emitter 311 and/or the light receiver 312, and the angles of the mirrors 321 and/or 322 may be adjusted by actuators respectively connected to the mirrors 321 and/or 322. The incidence height of light may be adjusted by adjusting the angle of the light emitter 311 and/or the angle of the light receiver 312, and/or the incidence angle of the light may be adjusted by adjusting the angles of the mirrors 321 and/or 322. In this case, the angle of the light emitter 311 and the angle of the light receiver 312 may correspond to an altitude angle, and the angles of the mirrors 321 and 322 may correspond to an azimuth angle.

The angle of the light emitter 311 may be adjusted such that light may be incident into (e.g., emitted into, transmitted to, etc.) the chamber at a target height. The angle of the submirror 321 may be adjusted such that light may be incident into the chamber at a target incidence angle. Referring to the view of FIG. 4, the incidence angle of light may be adjusted by adjusting the angle of the submirror 321. The angle of the light receiver 312 and the angle of the submirror 322 may be adjusted such that reflected light may be received by the light receiver 312. For example, the angle of the light receiver 312 may be adjusted in synchronization with the angle of the light emitter 311, and/or the angle of the submirror 321 may be adjusted in synchronization with the angle of the submirror 322, but the example embodiments are not limited thereto. For example, the angle of the light receiver 312 may be adjusted symmetrically with the angle of the light emitter 311, and/or the angle of the submirror 321 may be adjusted symmetrically with the angle of the submirror 322, etc.

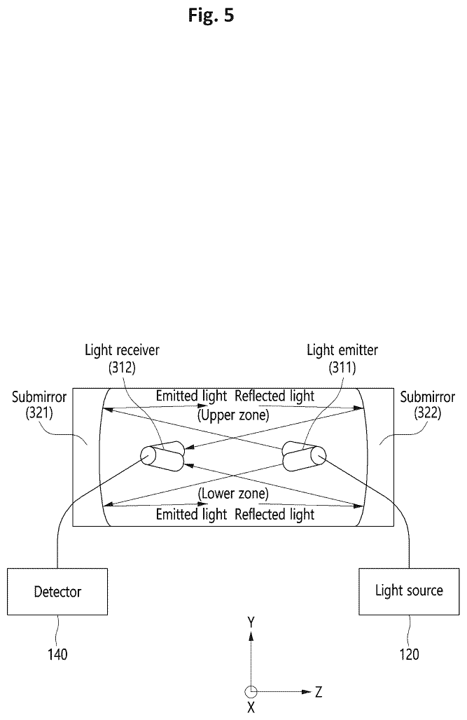

FIG. 5 is a diagram illustrating an incidence angle adjustment operation of a light path controller according to at least one example embodiment. Referring to FIG. 5, submirrors 321 and 322 may be concave mirrors, but are not limited thereto. One or more of the submirrors 321 and 322 may have a curvature for directing light in a desired direction, e.g., a direction parallel to a wafer supporter of a chamber, etc. The angle of a light emitter 311 may be adjusted such that light may be incident into the chamber at a target height. The angle of the submirror 321 may be adjusted such that light may be incident into the chamber at a target incidence angle. The angle of a light receiver 312 and the angle of the submirror 322 may be adjusted such that reflected light may be received by the light receiver 312. Referring to the view of FIG. 5, the incidence height of light may be adjusted by adjusting the angle of the light emitter 311, but is not limited thereto.

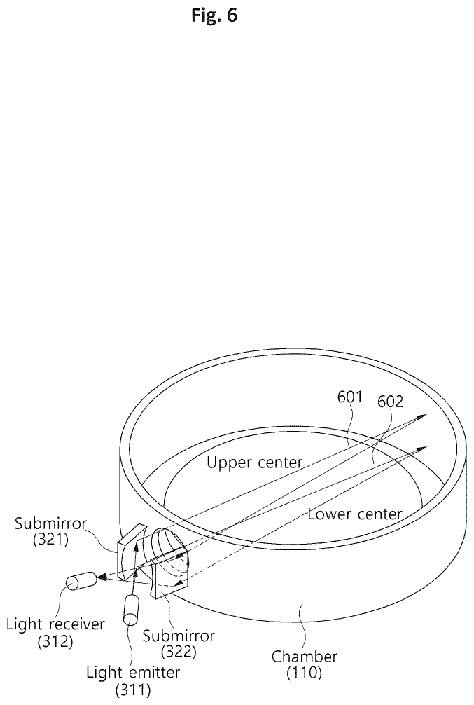

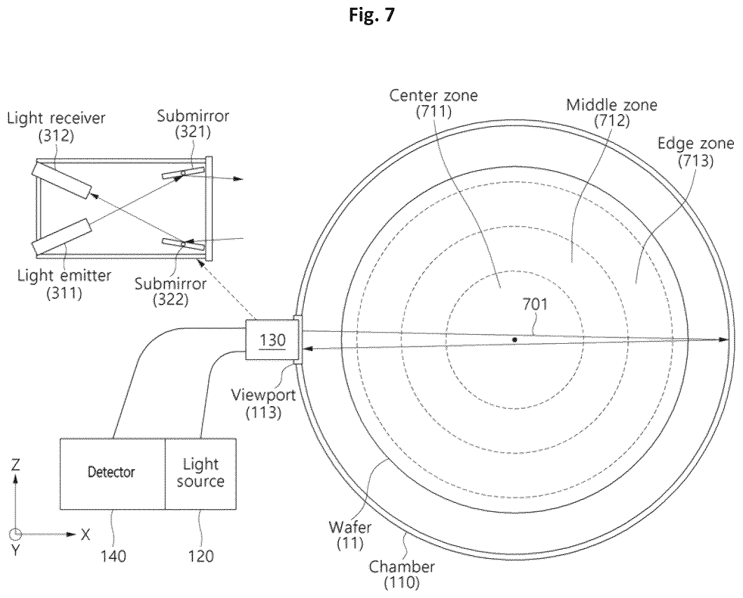

FIGS. 6 and 7 are diagrams illustrating an example in which optical paths are formed in a center zone according to at least one example embodiment. As described above, reference heights and/or reference incidence angles may be defined such that optical paths may pass through all zones inside a chamber 110, but are not limited thereto. For example, a first reference height for forming an optical path passing through an upper zone and a second reference height for forming an optical path passing through a lower zone may be defined, and a first incidence angle for forming an optical path passing through a center zone, a second incidence angle for forming an optical path passing through a middle zone, and a third incidence angle for forming an optical path passing through an edge zone, etc., may be defined.

Referring to FIG. 6, as an example, the concentration of radicals in an upper center zone and the concentration of radicals in a lower center zone may be sequentially measured, but the example embodiments are not limited thereto. The concentration of radicals in the upper center zone may be measured using an optical path 601, and the concentration of radicals in the lower center zone may be measured using an optical path 602, etc. To this end, a target height and a target incidence angle may be sequentially adjusted such that the optical paths 601 and 602 may sequentially and respectively pass through the upper center zone and the lower center zone, etc. For example, to measure the concentration of radicals in the upper center zone, the target height may be set to be the first reference height, and the target incidence angle may be set to be the first incidence angle etc. To measure the concentration of radicals in the lower center zone, the target height may be set to the second reference height, and the target incidence angle may be set to the first incidence angle, etc.

Referring to FIG. 7, an optical path 701 may be a view of the optical paths 601 and 602 of FIG. 6 in a Y-axis direction. The angles of a light emitter 311 and a submirror 321 may be adjusted as illustrated in FIG. 7 to form the optical paths 601 and 602, but is not limited thereto. For example, the angle of the light emitter 311 may be sequentially adjusted such that the target height may be adjusted to the first reference height or the second reference height, etc. In addition, the angle of the submirror 321 may be adjusted such that the target incidence angle may be adjusted to the first incidence angle, etc. For example, the target incidence angle may be about 0 degrees, but is not limited thereto, and the target incidence angle may be adjusted to any desired angle. The angles of a light receiver 312 and a submirror 322 may be adjusted as illustrated in FIG. 7 to receive light reflected along the optical paths 601 and 602, etc.

Although the optical path 701 is set to measure the concentration of radicals in a center zone 711, the optical path 701 may pass through not only the center zone 711 but also a middle zone 712 and an edge zone 713, or in other words, the optical path 701 may pass through the center zone 711 and one or more additional zones, etc. In this case, because the center zone 711 is a zone of interest, partial measurements in the middle zone 712 and the edge zone 713 may be excluded from the measurement along the optical path 701. For example, a length corresponding to the center zone 711, rather than the total length of the optical path 701, may be set as the length of an optical path of interest, and the concentration of radicals may be calculated based on the length of the optical path of interest. The amount of light absorbed in the middle zone 712 and the edge zone 713 may be estimated by substituting a length of the optical path 701 passing through the middle zone 712 and the edge zone 713 and a previously measured concentration of radicals in the middle zone 712 and the edge zone 713 into Equation 1, and the concentration of radicals along the length of the optical path of interest may be calculated by excluding the estimated amount of light absorbed in the middle zone 712 and the edge zone 713 from the total amount of light absorbed along the optical path 701, etc.

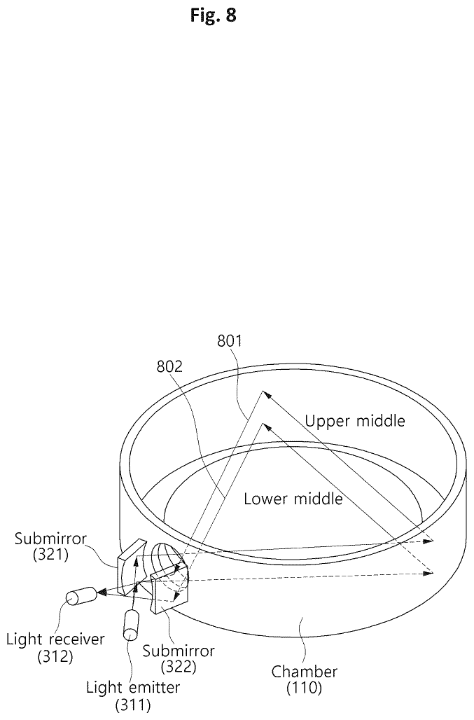

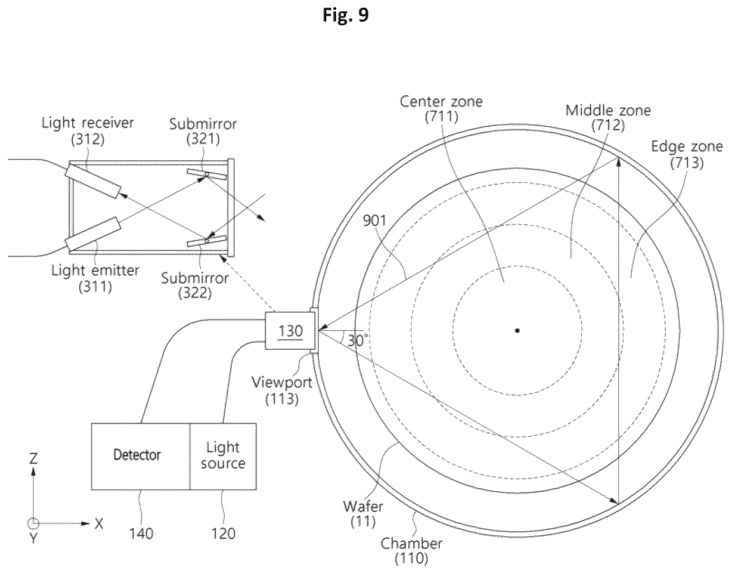

FIGS. 8 and 9 are diagrams illustrating an example in which optical paths are formed in a middle zone according to at least one example embodiment. Referring to FIG. 8, the concentration of radicals in an upper middle zone and the concentration of radicals in a lower middle zone may be sequentially measured. The concentration of radicals in the upper middle zone may be measured through an optical path 801, and the concentration of radicals in the lower middle zone may be measured through an optical path 802. To this end, a target height and a target incidence angle may be sequentially adjusted such that the optical paths 801 and 802 may sequentially and respectively pass through the upper middle zone and the lower middle zone. For example, to measure the concentration of radicals in the upper middle zone, the target height may be set to a first reference height, and the target incidence angle may be set to a second incidence angle. To measure the concentration of radicals in the lower middle zone, the target height may be set to a second reference height, and the target incidence angle may be set to the second incidence angle.

Referring to FIG. 9, an optical path 901 may be a view of the optical paths 801 and 802 of FIG. 8 in a Y-axis direction. The angles of a light emitter 311 and a submirror 321 may be adjusted as illustrated in FIG. 9 to form the optical paths 801 and 802, but are not limited thereto. For example, the angle of the light emitter 311 may be sequentially adjusted such that the target height may be adjusted to the first reference height or the second reference height, etc. In addition, the angle of the submirror 321 may be adjusted such that the target incidence angle may be adjusted to the second incidence angle. For example, the target incidence angle may be about 30 degrees, but is not limited thereto and may be any desired angle. The angles of a light receiver 312 and a submirror 322 may be adjusted as illustrated in FIG. 9 to receive light reflected along the optical paths 801 and 802, etc.

Although the optical path 901 is set to measure the concentration of radicals in a middle zone 712, the optical path 901 may pass through not only the middle zone 712 but also a center zone 711 and an edge zone 713, or in other words, the optical path may pass through a desired zone and one or more additional zones. In this case, because the middle zone 712 is a zone of interest, partial measurements in the center zone 711 and the edge zone 713 may be excluded from the measurement along the optical path 901. For example, a length corresponding to the middle zone 712, rather than the total length of the optical path 901, may be set as the length of an optical path of interest, and the concentration of radicals may be calculated based on the length of the optical path of interest. The amount of light absorbed in the center zone 711 and the edge zone 713 may be estimated by substituting a length of the optical path 901 passing through the center zone 711 and the edge zone 713 and a previously measured concentration of radicals in the center zone 711 and the edge zone 713 into Equation 1, and the concentration of radicals along the length of the optical path of interest may be calculated by excluding the estimated amount of light absorbed in the center zone 711 and the edge zone 713 from the total amount of light absorbed along the optical path 901.

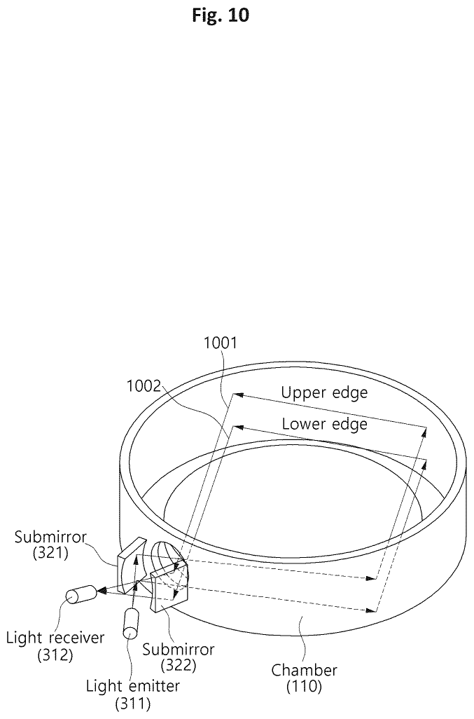

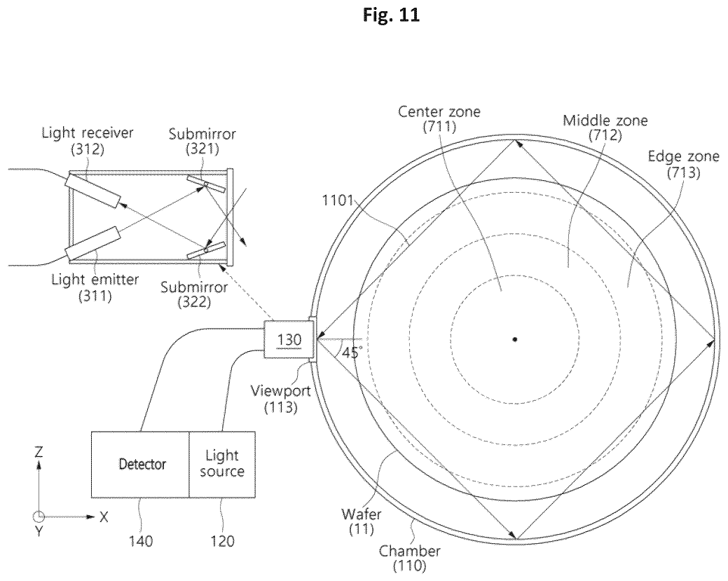

FIGS. 10 and 11 are diagrams illustrating an example in which optical paths are formed in an edge zone according to at least one example embodiment. Referring to FIG. 10, the concentration of radicals in an upper edge zone and the concentration of radicals in a lower edge zone may be sequentially measured, but the example embodiments are not limited thereto. The concentration of radicals in the upper edge zone may be measured through an optical path 1001, and the concentration of radicals in the lower edge zone may be measured through an optical path 1002, etc. To this end, a target height and a target incidence angle may be sequentially adjusted such that the optical paths 1001 and 1002 may sequentially and respectively pass through the upper edge zone and the lower edge zone. For example, to measure the concentration of radicals in the upper edge zone, the target height may be set to a first reference height, and the target incidence angle may be set to a third incidence angle. To measure the concentration of radicals in the lower edge zone, the target height may be set to a second reference height, and the target incidence angle may be set to the third incidence angle.

Referring to FIG. 11, an optical path 1101 may be a view of the optical paths 1001 and 1002 of FIG. 10 in a Y-axis direction. The angles of a light emitter 311 and a submirror 321 may be adjusted as illustrated in FIG. 11 to form the optical paths 1001 and 1002, but the example embodiments are not limited thereto. For example, the angle of the light emitter 311 may be sequentially adjusted such that the target height may be adjusted to the first reference height or the second reference height, etc. In addition, the angle of the submirror 321 may be adjusted such that the target incidence angle may be adjusted to the third incidence angle, etc. For example, the target incidence angle may be about 45 degrees, but is not limited thereto. The angles of a light receiver 312 and a submirror 322 may be adjusted as illustrated in FIG. 11 to receive light reflected along the optical paths 1001 and 1002, but the example embodiments are not limited thereto.

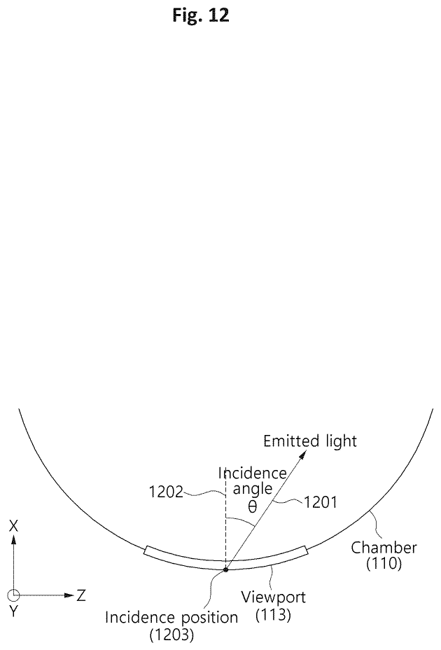

FIG. 12 is a diagram illustrating an incidence angle according to at least one example embodiment. Referring to FIG. 12, when an optical path 1201 is projected onto a bottom surface of a chamber 110, a line 1202 connecting an incidence position 1203 of light to the center of the bottom surface of the chamber 110 may be defined. Projecting the optical path 1201 onto the bottom surface of the chamber 110 may refer to viewing the optical path 1201 in a Y-axis direction. In this case, an incidence angle θ of the light may refer to the angle between the line 1202 and the optical path 1201.

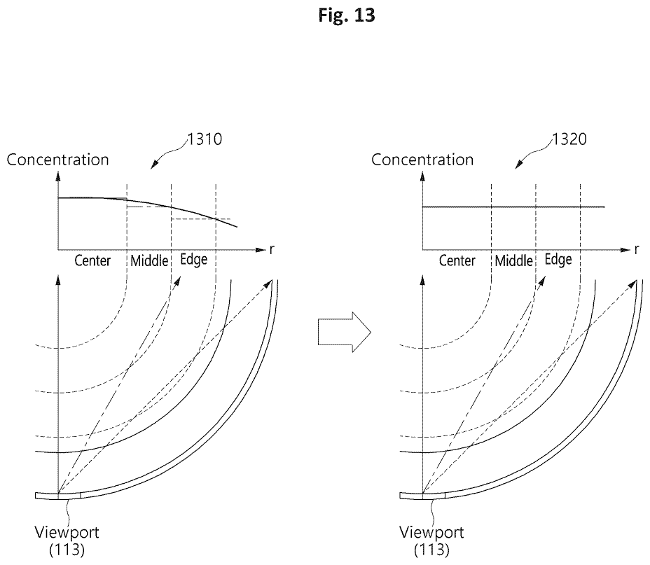

FIG. 13 is a diagram illustrating a distribution control operation based on results of radical concentration distribution measurement according to at least one example embodiment. Referring to FIG. 13, a measurement result 1310 may show that the concentration of radicals decreases in a direction from a center zone toward an edge zone, but the example embodiments are not limited thereto. A radical distribution, such as the measurement result 1310, may result in unbalanced and/or uneven cleaning of a wafer. In this case, the concentration of radicals may be controlled such that radicals are uniformly distributed and/or have an improved distribution in a chamber as illustrated in a measurement result 1320. As a result, balanced cleaning and/or improved cleaning of a wafer may be achieved.

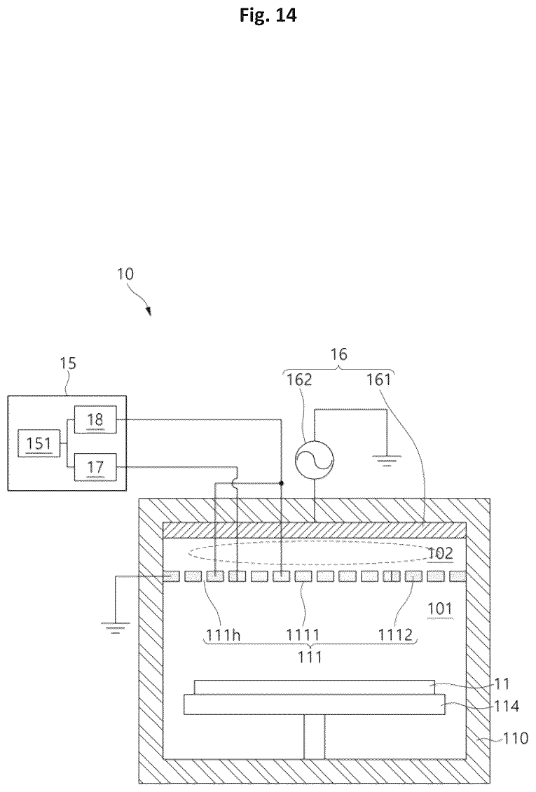

FIG. 14 is a diagram illustrating a configuration of semiconductor processing equipment 10 for controlling radical distribution according to at least one example embodiment. Referring to FIG. 14, the semiconductor processing equipment 10 may include at least one plasma source 16 and/or at least one temperature adjustment unit 15, but is not limited thereto. A chamber 110 may include a lower space 101 below an ion blocker 111 and an upper space 102 above the ion blocker 111. A wafer 11 may be processed in the lower space 101, and plasma may be generated in the upper space 102 by the plasma source 16.

The plasma source 16 may generate plasma from process gas supplied to the upper space 102. FIG. 14 illustrates an example in which a capacitively coupled plasma (CCP) source is used as the plasma source 16. However, the example embodiments are not limited thereto. For example, methods such as a method using a remote plasma source (RPS), a method using inductively coupled plasma (ICP), a method using microwaves, etc., may be used.

The plasma source 16 may include at least one upper electrode 161, at least one lower electrode, and/or at least one power supply 162, but the example embodiments are not limited thereto. FIG. 14 illustrates that the upper electrode 161 is attached to an upper end of the chamber 110. However, the upper electrode 161 may be provided in an upper internal space of the chamber 110, etc. The lower electrode may be provided in an internal space of a wafer supporter 114, but is not limited thereto. The power supply 162 may apply high-frequency power (for example, radio frequency (RF) power) and/or microwave power to the upper electrode 161 and/or the lower electrode. Power may be selectively applied to one of the upper electrode 161 and the lower electrode, and the other electrode may be electrically grounded. For example, power may be applied to the upper electrode 161, and the lower electrode may be grounded or vice versa.

The ion blocker 111 may divide the chamber 110 into the lower space 101 and the upper space 102. Process gas may be supplied to the upper space 102 through a gas supply unit (e.g., a gas supply, a gas supplier, a gas supply device, etc.). An electromagnetic field generated between the upper electrode 161 and the ion blocker 111 may excite the process gas into a plasma state.

The ion blocker 111 may include a plurality of through-holes 111h formed in a vertical direction. Among plasma effluents, radicals and/or neutral gas may pass through the through-holes 111h of the ion blocker 111. However, charged species (for example, ions) may have difficulty in passing through the through-holes 111h of the ion blocker 111. For example, when the process gas used to generate plasma is nitrogen trifluoride (NF₃), fluorine-containing radicals (e.g., F*, NF3*, etc.) may pass through the ion blocker 111.

The ion blocker 111 may include a plurality of zones 1111 and 1112, etc. The ion blocker 111 may be connected to the temperature adjustment unit 15 (e.g., temperature adjustment device, etc.). The temperature adjustment unit 15 may include a heater 18, a chiller 17, and/or a control unit 151, etc., and the control unit 151 may control the heater 18 and/or the chiller 17. The control unit 151 may be configured to perform temperature control for each zone of the ion blocker 111 and may include at least one processor (e.g., processing circuitry) and at least one memory device, but is not limited thereto. The plurality of zones 1111 and 1112 may respectively include heating lines. The heating lines may be respectively connected to heaters of the heater 18, and the temperatures of the zones 1111 and 1112 may be independently controlled. The heating lines may include, for example, electric resistance heating elements, inductive heating elements, etc., but are not limited thereto.

As the temperatures of the zones 1111 and 1112 are independently controlled, the concentration of radicals in one or more zones (for example, an upper center zone, an upper middle zone, an upper edge zone, a lower center zone, a lower middle zone, and/or a lower edge zone, etc.) inside the chamber 110 may be controlled. For example, when the concentration of radicals decreases in a direction from a center zone toward an edge zone of the chamber 110 as illustrated in FIG. 13, the temperatures of the zones 1111 and 1112 may be controlled to increase the concentration of radicals in the edge zone, etc.

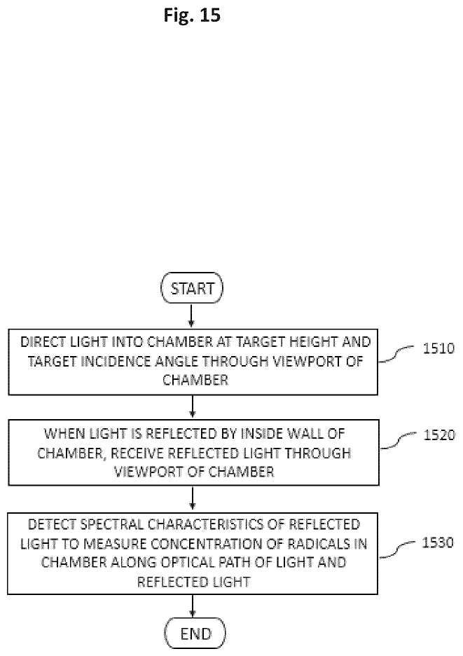

FIG. 15 is a flowchart illustrating a method of measuring the concentration of radicals based on light absorption, according to at least one example embodiment. Referring to FIG. 15, in operation 1510, light may be directed into a chamber at a target height and a target incidence angle through a viewport of the chamber. In operation 1520, when the light is reflected by an inside wall (e.g., interior surface, etc.) of the chamber, the reflected light may be received through the viewport of the chamber. In operation 1530, spectral characteristics of the reflected light may be detected to measure the concentration of radicals in the chamber along an optical path of the light and the reflected light. Operations 1510 and 1520 may be performed by a light path controller. Operation 1530 may be performed by a detector.

The light path controller may include a light emitter configured to direct light into the chamber and a light receiver configured to receive reflected light. At least one of the light emitter and the light receiver may have an angle adjustment function. The light path controller may further include an actuator to implement the angle adjustment function. The light path controller may further include at least one mirror configured to reflect light, emitted by the light emitter, toward the inside of the chamber, and to reflect light, reflected by the inside wall of the chamber, toward the light receiver. The mirror may have an angle adjustment function. The mirror may be a concave mirror having a curvature for directing light into the chamber in a direction parallel to a wafer supporter of the chamber, but is not limited thereto.

The light path controller may control the optical path by sequentially using a target height and a target incidence angle that are sequentially selected from reference heights and reference incidence angles defined based on one or more zones inside the chamber. The concentration of radicals in the one or more zones may be sequentially measured by the sequential use of the target height and the target incidence angle.

The inside wall of the chamber may have a cylindrical structure and include a light-reflective material, but is not limited thereto. The semiconductor processing equipment may be used for a dry cleaning process. The concentration of radicals may be measured by analyzing light absorption along the optical path based on spectral characteristics.

While some example embodiments have been described with reference to the accompanying drawings, it will be understood by those of ordinary skill in the art that various technical modifications and variations may be made to the example embodiments. For example, appropriate results may be obtained even when the techniques described above are performed in an order different from the methods described above, and/or elements of systems, structures, devices, circuits, etc., are coupled and/or combined with each other differently from the methods described above and/or are replaced and/or substituted by other elements and/or equivalents thereof.

Therefore, such other implementations, example embodiments, and equivalents to the appended claims should be construed as being included within the scope of the claims.

What is claimed is:

1. Semiconductor process equipment comprising:
a chamber including a viewport;
a light source configured to generate light;
a light path controller configured to,
direct the light into the chamber through the viewport at a target height and a target incidence angle, and
receive reflected light through the viewport when the light is reflected by an interior surface of the chamber; and
a detector configured to,
detect spectral characteristics of the reflected light, and
measure a radical concentration in the chamber along an optical path of the light and the reflected light based on the detected spectral characteristics.

2. The semiconductor process equipment of claim 1, wherein the light path controller comprises:
a light emitter configured to direct the light into the chamber; and
a light receiver configured to receive the reflected light,
wherein at least one of the light emitter and the light receiver has an angle adjustment function.

3. The semiconductor process equipment of claim 2, wherein the light path controller further comprises:
at least one actuator configured to adjust an angle of at least one of the light emitter and the light receiver.

4. The semiconductor process equipment of claim 2, wherein the light path controller further comprises:
at least one mirror configured to,
reflect the light output from the light emitter into the chamber, and
reflect the light reflected by the interior surface of the chamber toward the light receiver.

5. The semiconductor process equipment of claim 4, wherein the at least one mirror has an angle adjustment function.

6. The semiconductor process equipment of claim 4, wherein
the chamber includes a wafer supporter; and
the at least one mirror includes concave mirror having a curvature, the concave mirror configured to direct the light in a direction parallel to the wafer supporter.

7. The semiconductor process equipment of claim 1, wherein
the light path controller is further configured to control the optical path of the light by adjusting the target height and the target incidence angle based on at least one target zone within the chamber; and
the detector is further configured to measure the radical concentration in the at least one target zone using the target height and the target incidence angle.

8. The semiconductor process equipment of claim 1, wherein the interior surface of the chamber has a cylindrical structure and comprises a light-reflective material.

9. The semiconductor process equipment of claim 1, wherein the semiconductor process equipment is used for a dry cleaning process.

10. The semiconductor process equipment of claim 1, wherein the detector is further configured to:
measure the radical concentration by analyzing light absorption along the optical path based on the spectral characteristics.
